(19) United States
(12) Patent Application Publication
(10) Pub. No.: US 2011/0235249 A1
(43) Pub. Date: Sep. 29, 2011

(54) WORK SURFACE ARTICULATION

(75) Inventors: Benjamin Shane Bustle, Charlotte, NC (US); Jacob Connelly, Concord, NC (US); Robert Grant McRorie, Huntersville, NC (US)

(73) Assignee: RUBBERMAID INCORPORATED, Huntersville, NC (US)

(21) Appl. No.: 13/016,190

(22) Filed: Jan. 28, 2011

Related U.S. Application Data
(60) Provisional application No. 61/299,640, filed on Jan. 29, 2010.

(51) Int. Cl. H05K 7/00; A47B 37/00; A47B 81/00

(52) U.S. Cl. 361/679.01; 108/18; 312/328

(57) ABSTRACT

A workstation comprises a support and a work platform mounted on the support by an articulation mechanism. The articulation mechanism pivots the work platform between a storage position and a deployed position about a pivot axis and raises the pivot axis relative to the support as the work platform moves from the storage position to the deployed position. The workstation comprises a support supporting a flat monitor in a monitor housing having a depth. In the storage position the work platform is located below the monitor and in the deployed position the work platform may be used as a keyboard support and a desk.

This application claims benefit of priority under 35 U.S.C. §119(e) to the filing date of to U.S. Provisional Application No. 61/299,640, as filed on Jan. 29, 2010, which is incorporated herein by reference in its entirety.

### BACKGROUND

The invention relates to work stations for supporting display monitors and user input devices such as keyboards on a wall or other vertical surface. The work stations are typically mounted to a wall and comprise a support structure that may be moved by the end user to position the display, keyboard or the like at a desired height. Such work surfaces may be difficult to operate, do not move to a proper ergonomic position or are not maintained in the desired position.

### SUMMARY OF THE INVENTION

A workstation comprises a support. A work platform is mounted on the support by an articulation mechanism where the articulation mechanism pivots the work station between a storage position and a deployed position about a pivot axis and raises the pivot axis relative to the support as the work station moves from the storage position to the deployed position.

A monitor may be mounted directly above the work platform when the work platform is in the storage position. The monitor may be a flat panel monitor having a depth and the work station fits within the depth when the work station is in the storage position. The work platform may be in a vertical orientation when the work station is in the storage position. The work platform may be in a horizontal orientation when the work platform is in the deployed position. The pivot axis may be mounted on a slide that is movable vertically relative to the support. The pivot axis may be mounted at the rear end of the work station. A link may connect the work station to the support. One end of the link may be fixed in position relative to the support. The link may be in an on-center position when the work station is in the storage position. The work platform may support a keyboard. The work platform may comprise a flat work surface. A movable tray may be supported on the work platform such that the tray can be moved between a retracted position and an extended position when the work platform is in the deployed position.

A workstation comprises a support supporting a flat monitor in a monitor housing having a depth. A work platform is mounted on the support by an articulation mechanism where the articulation mechanism pivots the work station between a storage position where the work platform is located below the monitor and is within the depth and a deployed position where the work station extends substantially horizontally. The work station pivots about a pivot where the pivot is supported for linear movement relative to the support such that the pivot moves toward the monitor as the work station moves from the storage position to the deployed position. The workstation may comprise a link pivotably connected at one end to a first fixed pivot on the support and at an opposite end at a second fixed pivot to the work platform; and a slide bar mounted for vertical sliding movement in the support where the pivot connects the slide bar to the work platform such that work platform may freely pivot relative to the slide bar.

A method of operating a work station comprises providing a work station having a monitor and a keyboard supported on a work platform; pivoting the work platform about a pivot from a substantially vertical position where it is positioned below the monitor to a substantially horizontal position; moving the pivot vertically as the work platform pivots; supporting the work platform in the substantially horizontal position. The method may further comprise using the work platform as a desk.

### BRIEF DESCRIPTION OF THE DRAWINGS

FIG. 1 is a perspective view showing an embodiment of a work station with an embodiment of the work surface articulation mechanism.

FIG. 2 is a perspective view of the work station of FIG. 1 with the work platform in a deployed position.

FIG. 3 is a perspective view of the work station of FIG. 1 with the work platform in a deployed position showing the work surface articulation mechanism.

FIG. 4 is a side view of the work station of FIG. 1 with the work platform in a fully raised storage position showing the work surface articulation mechanism.

FIGS. 5 and 6 are side views of the work station similar to FIG. 4 with the work platform in progressively lowered positions.

FIG. 7 is a side view of the work station similar to FIG. 4 with the work platform in a fully lowered deployed position.

FIG. 8 is a more detailed view of the work surface articulation mechanism.

FIG. 9 is a perspective view of an embodiment of the keyboard tray and drawer used in the work station of FIG. 1.

FIG. 10 is a bottom perspective view of the keyboard tray and drawer of FIG. 9 with the work surface retracted.

FIG. 11 is a bottom perspective view of the keyboard tray and drawer of FIG. 9 with a mouse surface deployed.

FIG. 12 is a perspective view showing an alternate embodiment of the work surface articulation mechanism.

### DETAILED DESCRIPTION OF EMBODIMENTS OF THE INVENTION

The workstation described herein uses a work surface articulation mechanism that moves the work surface from a retracted storage position to a deployed use position where in the deployed position the work surface is properly ergonomically positioned relative to a co-mounted monitor. The work surface articulation mechanism is easy to operate by the end user and automatically and quickly positions the work surface. The work station has particular application in medical environments such as hospitals or the like.

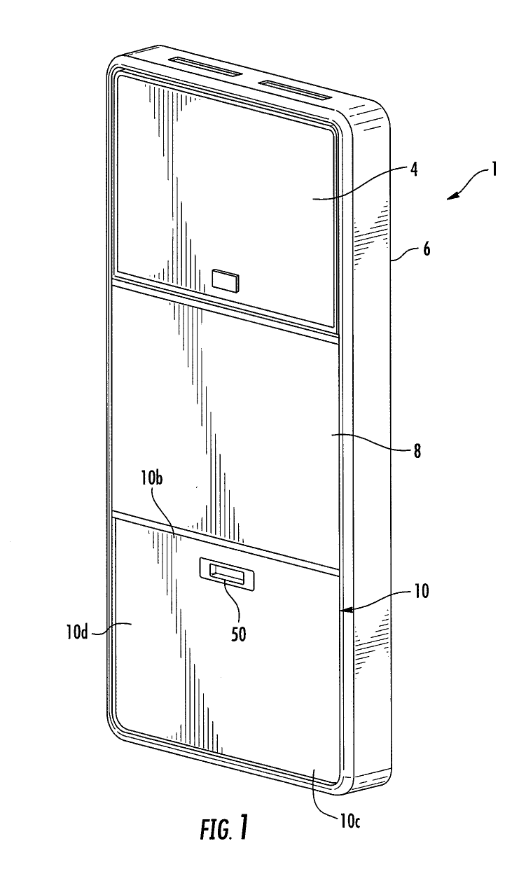

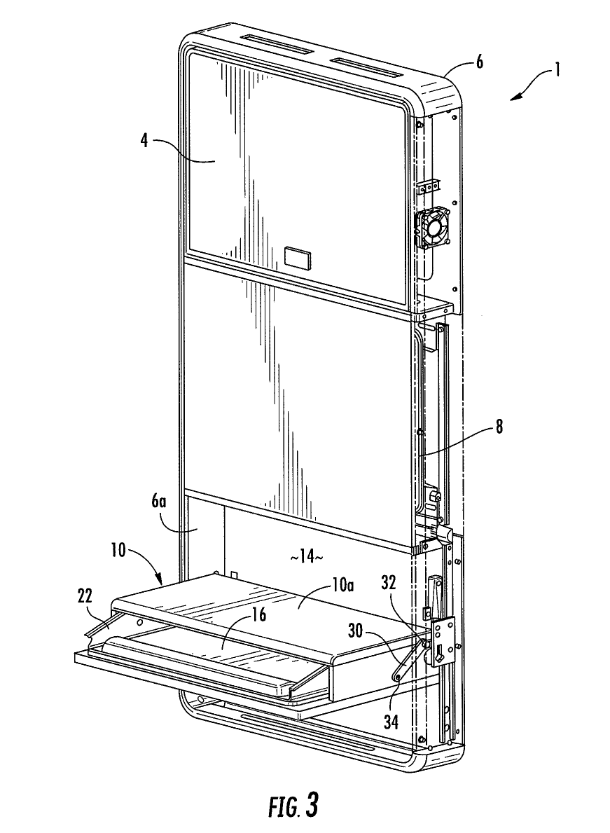

Referring to FIGS. 1 through 3 the work station is shown generally at 1 and comprises a support 6 that may be adapted to be secured to a wall or other vertical structure. The support 6 constitutes a housing or frame for retaining the various components of the work station in a single unit where the mechanical components are isolated from the external environment. While the illustrated work station is a fixed platform, the work surface articulation mechanism may be used on a mobile platform such as a cart based work station where the support 6 is mounted on or forms a part of the rolling cart. Support 6 holds equipment such as a monitor 8 and work platform 10. The work station 1 is particularly well suited for healthcare applications such as in a patient room although it may be used in a wide variety of applications. In such a healthcare environment minimizing the use of space is important for user comfort and healthcare professional-to-patient interaction.

Support 6 supports work platform 10, a monitor 8 and a computer 5 located in a locked computer compartment 4. The work platform 10 supports a keyboard tray 16 that supports a keyboard 18. The work platform 10 comprises a work surface 10a that occupies a substantially horizontal orientation when the work platform is in the illustrated use position. Providing a substantially horizontal work surface 10a on the work platform 10 allows the work surface 10a to be used as a desk-type support for papers, medication and other equipment while simultaneously allowing the user to access the keyboard. The work platform 10 supports keyboard tray 16 where, in one embodiment, the keyboard tray 20 is mounted on a drawer 22 where the drawer may be moved between a retracted position where it is located below work surface 10a and an extended use position where it is extended from below the work surface 10a where it may be accessed by a user. The drawer 22 may be supported on runners 24 that are supported by rollers or other anti-friction device that allow the runners to slide into and out of the work platform 10 when the drawer 22 is pushed and pulled between the extended and retracted positions.

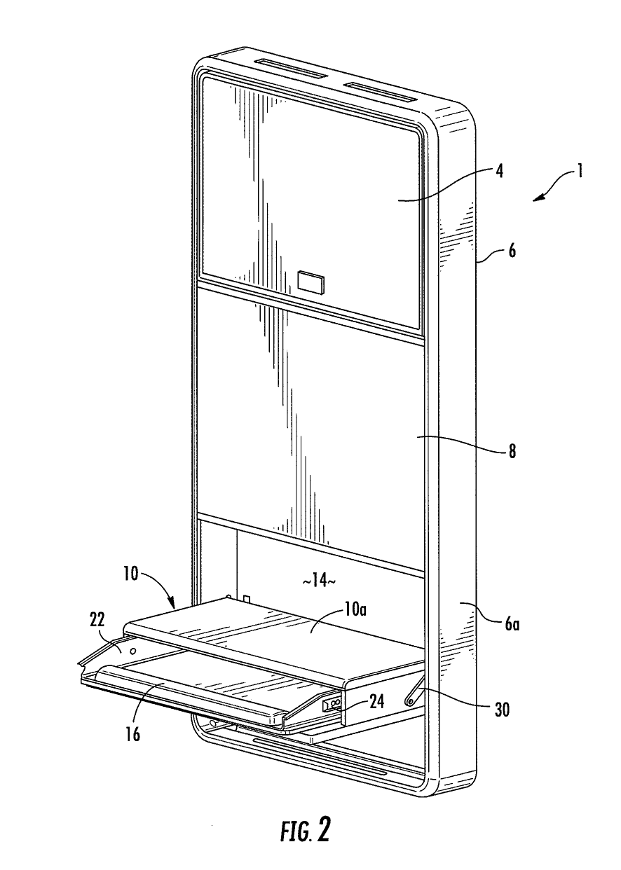

The work platform 10 is pivoted to the support 6 such that it can be moved from a substantially vertical storage position (FIG. 1) to a substantially horizontal deployed position (FIG. 2). In the vertical storage position the work platform 10 is located in a compartment 14 formed in support 6 and is positioned directly below and in the same plane as the monitor 8. The computer compartment 4, monitor 8 and work platform 10 are dimensioned such that the work station has a narrow depth where the work platform, when in the storage position, has the same or similar depth as the flat monitor in support 6.

The work platform 10 is pivoted from the storage position to the deployed position and, as it is pivoted, the work platform 10 is raised relative to the monitor 8 such that the work platform 10 is spaced an ergonomically comfortable distance below the monitor 8. If the work platform 10 was to be simply hinged at its bottom end to the support 6, the work platform 10, when moved to the open position, would be spaced too far from the monitor 8 to be at an ergonomically comfortable position relative to the monitor. The work platform articulation mechanism raises the work platform 10 as it pivots to the open deployed position to automatically move the work platform toward the monitor and position the work platform 10 relative to the monitor 8 at the appropriate distance.

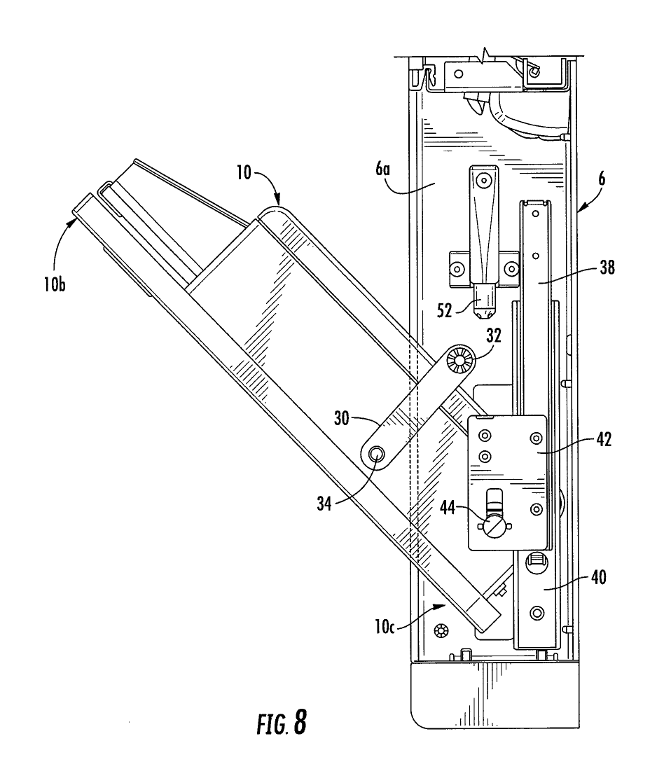

An articulation mechanism is located on each side of the work platform 10 for connecting the work platform 10 to the support 6. One of the articulation mechanisms will be described, it being understood that the other articulation mechanism is identical. Referring to FIG. 8, the articulation mechanism comprises a link 30 pivotably connected at one end to a fixed pivot 32 mounted to the side wall 6a of the support 6. Link 30 may be pivotally connected to the side wall 6 by a pivot pin where the pin is mounted at a fixed location on the wall 6a. The opposite end of link 30 is pivotably connected at a fixed pivot 34 to a central area of the work platform 10 between front end 10b and back end 10c. Link 30 may be pivotably connected to the work platform 10 by a pivot pin where the pin is mounted at a fixed location on a side of the work platform 10.

A slide bar 38 is mounted for vertical sliding movement in the side wall 6a of support 6. The slide bar 38 may be mounted on a rail 40 having rollers, ball bearings or other anti-friction device such that the slide bar 38 can freely slide relative to the support 6. A plate 42 is fixed to the slide bar 38 and a pivot pin 44 connects the plate 42 to the back end 10c of the work platform 10 such that work platform 10 may freely pivot relative to the slide bar 38 about pin 44.

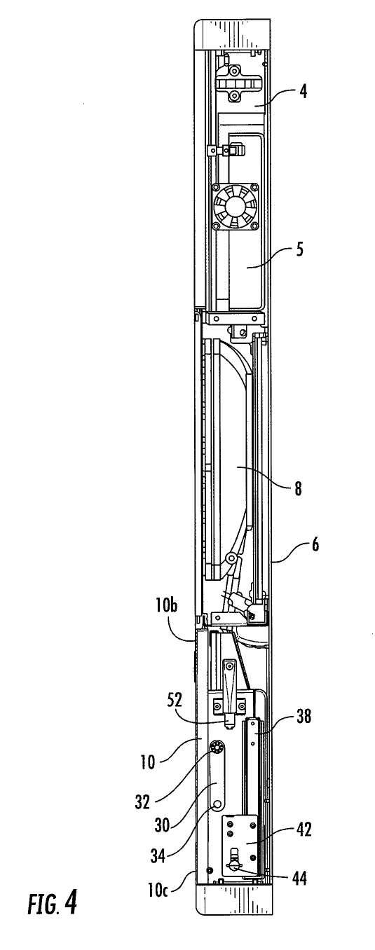

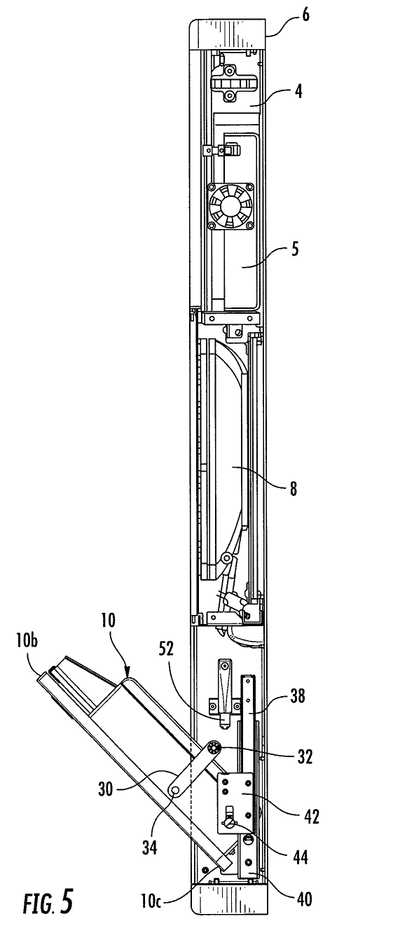

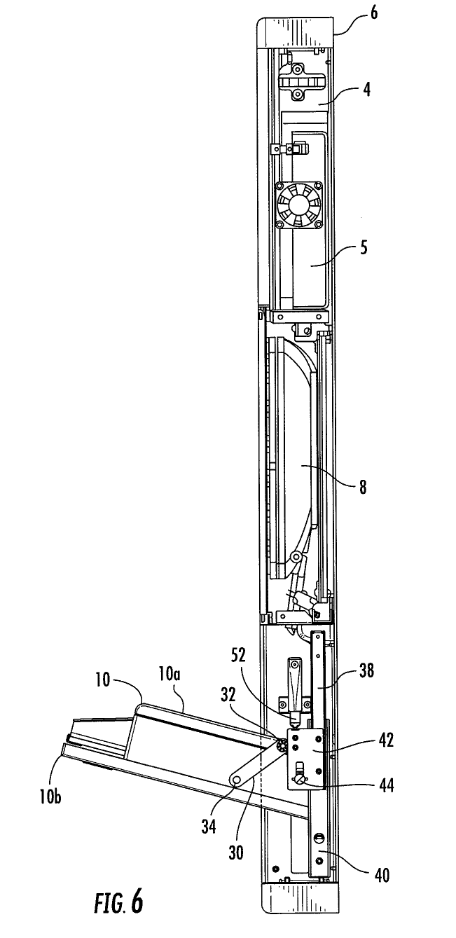

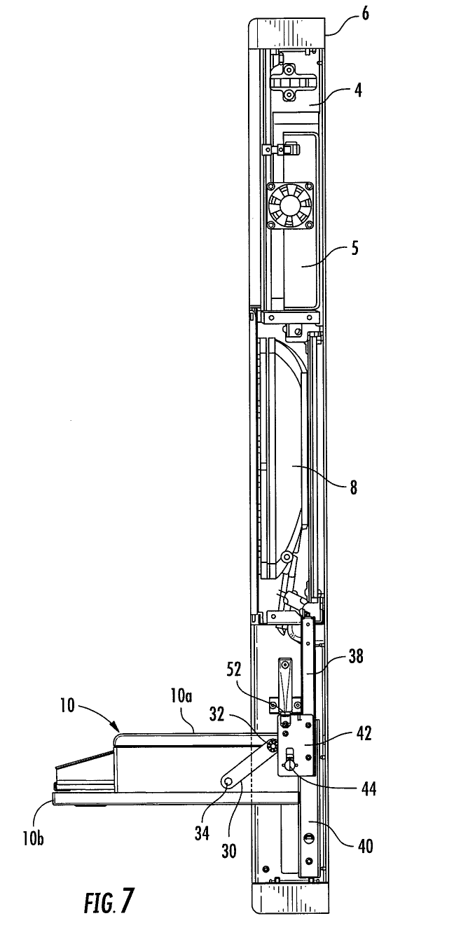

Referring to FIGS. 4 through 7, to move the work platform 10 from the vertical storage position (FIG. 4) to the horizontal deployed position (FIG. 7), a user pulls the front end 10b of the work platform 10 away from support 6. The face 10d of the work platform 10 may be provided with a handle 50 to facilitate the user's grip on the work platform (FIG. 1). Referring to FIGS. 5 and 6, as the front end 10b of the work platform 10 pivots away from the support 6, the work platform 10 simultaneously pivots about pin 44 and pin 34. Link 30 also pivots away from support 6 about pivot pin 32. As the work platform 10 pivots, the back end 10c of the work platform 10, pivot 44 and slide 38 move vertically upward relative to the support 6. The back end 10c of the work platform 10 moves vertically upward because link 30 limits the downward movement of the work platform and the slide 38 constrains movement of pin 44 to vertical movement. The work platform 10 rotates about pin 34 with the front end 10b of the work platform 10 moving downward as the back end 10c of the work platform 10 moves upward. This motion continues until the work platform reaches the horizontal or nearly horizontal deployed position (FIGS. 2 and 7).

When the work platform 10 reaches the deployed position, movement of the work station is stopped by the engagement of plate 42 with stop 52. Because the slide 38 is prevented from moving beyond this point, the work platform 10 may not pivot beyond the deployed position. In the deployed position, the back end 10c of the work platform 10 is fixed in position by the slide and the work platform 10 is supported in the horizontal position by link 30. While in the illustrated embodiment the deployed position is horizontal it is to be understood that in the deployed position the work platform 10 may assume other angular orientations relative to horizontal. The distance pivot 34 is positioned from the monitor 8 determines the distance the work platform 10 is from the monitor 8 in the deployed position. This distance can be set to achieve the optimal ergonomic relationship between the monitor 8 and work platform 10. Because the work platform 10 supports a keyboard tray and keyboard the distance between the monitor and work platform also sets the distance between the monitor and keyboard.

To return the work platform 10 from the deployed position to the storage position, the user lifts the front end 10b of the work platform 10 and rotates the front end 10b toward the support 6. As the work platform 10 is rotated, the back end of the work platform rotates relative to the slide 38 about pin 44 and pulls the slide 38 vertically downward. The work platform 10 also pivots about link 30 and causes the link 30 to rotate about pin 32 toward the support. The slide 38 continues to move downward and the work platform 10 is rotated until the work platform is in the vertical storage position in compartment 14 directly below monitor 8, as shown in FIG. 4. In the storage position the link 30 occupies an on-center or over-center position where the weight of the work platform 10 maintains the work platform 10 in the storage position.

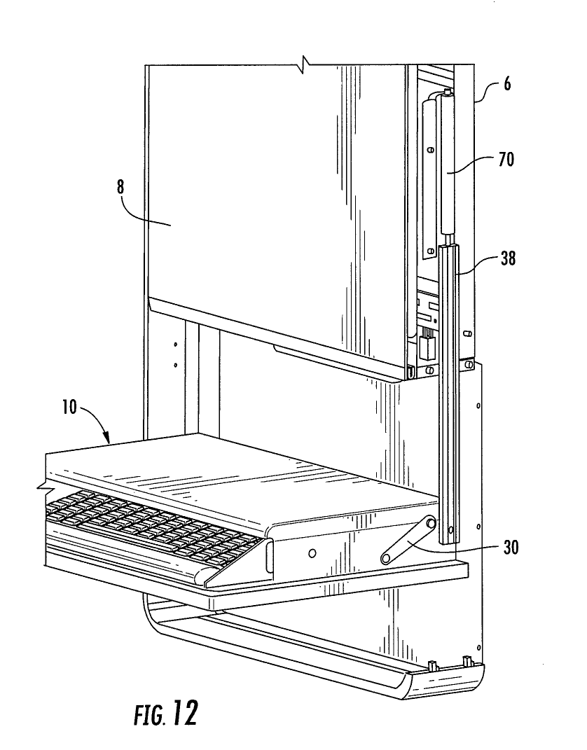

Referring to FIG. 12, where like reference numerals are used to identify the same components previously described with reference to FIGS. 1 through 7, a counterweight 70 such as a gas damper may be provided to limit the speed of movement of the work platform 10 as it moves between the storage position and the deployed position. The gas damper 70 is shown connected between the slide 38 and the support 6 to slow the speed of the slide as it moves in the support; however, the damper 70 may be connected between other of the components.

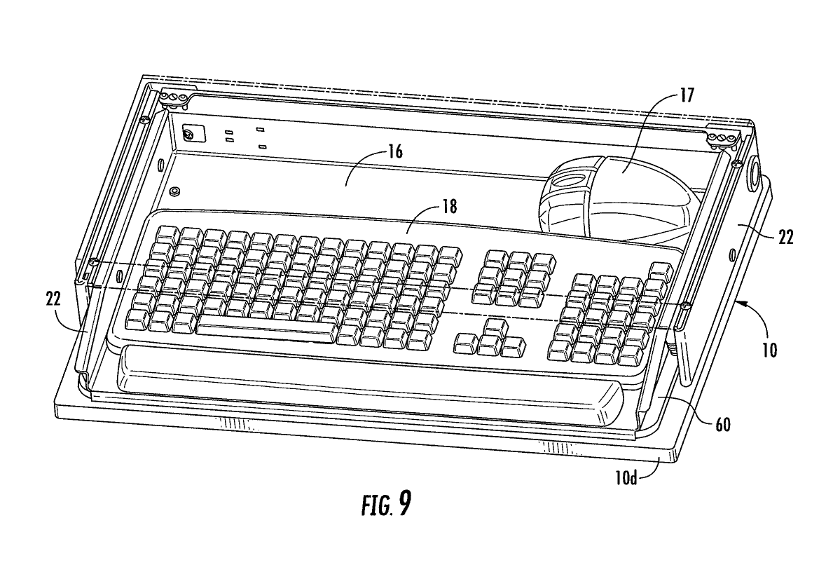

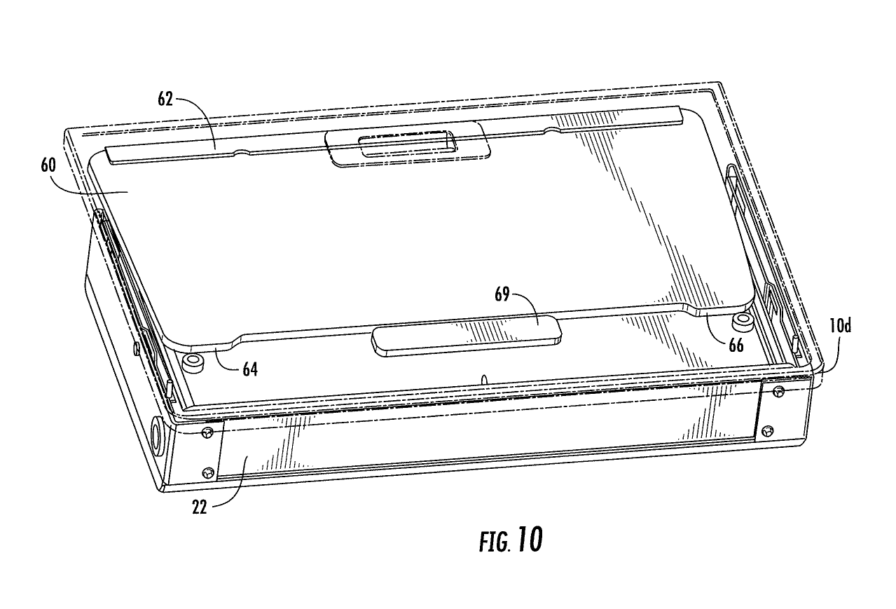

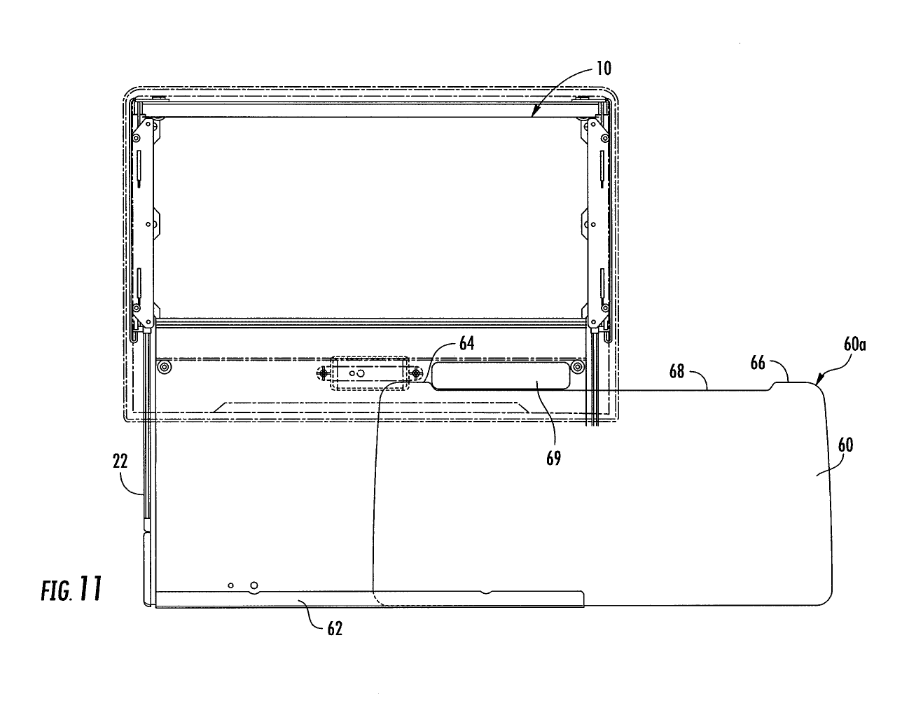

FIG. 9 shows the work platform 10 with the work surface 10a removed to reveal a keyboard 18 supported on tray 16. Tray 16 also supports a mouse 17. In order to provide a surface for supporting the mouse and/or other end user equipment a movable mouse platform 60 is supported on the bottom of the drawer 22 where the mouse platform 60 can be moved between a retracted position (FIGS. 9 and 10) to an extended position (FIG. 11) when the drawer 22 is extended. The front edge of the mouse platform 60 is supported in a channel 62 and the back edge of the tray is supported by the front panel 10d of work platform 10. The mouse platform 60 may be pulled laterally from under the drawer 22 as shown in FIG. 11 to provide a work surface that may be used as a mouse tray. FIG. 11 shows the mouse platform 60 pulled from one side of the drawer the mouse platform 60 may also be pulled from the other side of the drawer such that the mouse platform 60 may be positioned to either the right or left of the drawer 22. The back edge 60a of the mouse platform 60 includes a pair of protrusions 64, 66 defining a recess 68 between the protrusions. The recess 68 receives a stop 69 where the stop 69 engages a first one of the protrusions 64 to limit the distance that the tray may be pulled from the drawer in the first direction and the other protrusion 66 limits how far the mouse platform 60 may be pulled from the drawer 22 in the second direction. While platform 60 has been described as a mouse platform, the mouse platform 60 may support other items in addition to or in place of the mouse.

Specific embodiments of an invention are disclosed herein. One of ordinary skill in the art will recognize that the invention has other applications in other environments. Many embodiments are possible. The following claims are in no way intended to limit the scope of the invention to the specific embodiments described above.

1. A workstation comprising:
a support;
a work platform mounted on the support by an articulation mechanism where the articulation mechanism pivots the work platform between a storage position and a deployed position about a pivot axis and raises the pivot axis relative to the support as the work platform moves from the storage position to the deployed position.

2. The workstation of claim 1 wherein a monitor is mounted directly above the work platform when the work platform is in the storage position.

3. The workstation of claim 1 wherein the monitor is a flat screen monitor having a depth and the work platform fits within the depth when the work platform is in the storage position.

4. The workstation of claim 1 wherein the work platform is in a vertical orientation when the work platform is in the storage position.

5. The workstation of claim 1 wherein the work platform is in a horizontal orientation when the work platform is in the deployed position.

6. The workstation of claim 1 wherein the pivot axis is mounted on a slide that is movable vertical relative to the support.

7. The workstation of claim 6 wherein the pivot axis is mounted at the rear end of the work station.

8. The workstation of claim 1 wherein a link connects the work platform to the support.

9. The workstation of claim 1 wherein one end of the link is mounted on a fixed pivot to the support.

10. The workstation of claim 1 wherein the link is in an on-center position when the work platform is in the storage position.

11. The workstation of claim 1 wherein the work platform supports a keyboard.

12. The workstation of claim 1 wherein the work platform comprises a flat work surface.

13. The workstation of claim 1 wherein a movable mouse platform is supported on the work platform such that the tray can be moved between a retracted position and an extended position when the work platform is in the deployed position.

14. A workstation comprising:
a support adapted to support a flat monitor in a monitor housing having a depth;
a work platform mounted on the support by an articulation mechanism where the articulation mechanism pivots the work platform between a storage position where the work platform is located below the monitor and is within the depth and a deployed position where the work platform extends substantially horizontally, the work platform pivoting about a pivot where the pivot is supported for linear movement relative to the support such that the pivot moves toward the monitor as the work platform moves from the storage position to the deployed position.

15. The workstation of claim 14 articulation mechanism comprises a link pivotably connected at one end to a first fixed pivot on the support and an opposite end of the link being pivotably connected at a second fixed pivot to the work platform; and a slide bar mounted for vertical sliding movement in the support, and the pivot connecting the slide bar to the work platform such that work platform may freely rotate relative to the slide bar.

16. A method of operating a work station comprising:
providing a work platform having a monitor and a keyboard supported on a work platform;
pivoting the work platform about a pivot from a substantially vertical position where it is positioned below the monitor to a substantially horizontal position;
moving the pivot vertically as the work platform pivots;
supporting the work platform in the substantially horizontal position.

17. The method of claim 16 further comprising using the work platform as a work surface.
